(19) United States
(12) Patent Application Publication
(10) Pub. No.: US 2025/0290954 A1
(43) Pub. Date: Sep. 18, 2025

(54) PROBE HEAD WITH ADJUSTABLE PROTRUSION LENGTH OF PROBE

(71) Applicant: TSE CO., LTD., Cheonan-si, Chungcheongnam-do (KR)

(72) Inventors: Seung Bae AN, Cheonan-si (KR); Young Hun JU, Cheonan-si (KR)

(73) Assignee: TSE CO., LTD., Cheonan-si, Chungcheongnam-do (KR)

(21) Appl. No.: 18/858,982

(22) PCT Filed: Nov. 9, 2022
(86) PCT No.: PCT/KR2022/017534

§ 371 Date: Oct. 22, 2024

(30) Foreign Application Priority Data
Apr. 27, 2022 (KR) 10-2022-0051899

(51) Int. Cl. G01R 1/073; G01R 1/04

(52) U.S. Cl. CPC G01R 1/07364; G01R 1/0416; G01R 1/07314

(57) ABSTRACT

Disclosed is a probe head configured such that a support distance is changed based on variation of a support axis extending through a plate and a spacer, whereby the protrusion length of a probe is adjusted. Since the protrusion length of the probe under a lower plate is adjusted, the number of tests is increased, and therefore the lifespan of the probe head is extended. In addition, work time for replacement and reinstallation of the probe head is shortened, whereby delay of a test process is prevented and process cost is reduced.

### TECHNICAL FIELD

The present invention relates to a probe head for testing semiconductor elements, and more particularly to a probe head configured such that a support distance is changed based on variation of a support axis extending through a plate and a spacer, whereby the protrusion length of a probe is adjusted.

### BACKGROUND ART

In general, a semiconductor device manufacturing process includes a patterning process of manufacturing semiconductor elements, an electrical die sorting (EDS) process of electrically testing the semiconductor elements to determine whether the semiconductor elements are defective, and an assembly process of integrating the semiconductor elements on a wafer.

In the EDS process, which is a process of supplying test current to the semiconductor elements and testing electrical signals output from the semiconductor elements to determine whether the semiconductor elements are defective, a probe apparatus configured such that a probe is electrically brought into contact with the semiconductor elements to test performance of the semiconductor elements is widely used.

The probe apparatus includes a tester configured to supply test current and to test and analyze a signal based thereon, a probe card configured to electrically connect an object to be tested (a semiconductor element) and the tester to each other, and a probe configured to be brought into direct contact with the object to be tested and a printed circuit board of the probe card.

The probe is generally configured to have a probe head structure in which a plurality of probes is received and assembled such that the probes stably contact the object to be tested and the probe card while maintaining an appropriate contact pressure and durability of the probes is guaranteed even after a plurality of tests.

In general, the probe head is constituted by a probe and a plate assembly in which the probe is received and assembled. The probe is received in the plate assembly such that a first contact tip and a second contact tip of the probe protrude outwards from a first surface and a second surface of the plate assembly, respectively, so as to electrically contact the printed circuit board and a contact terminal of a semiconductor element to be tested at an appropriate pressure.

The plate assembly may be configured to have various structures capable of receiving and supporting the probe. For a general vertical probe, the plate assembly mainly includes an upper plate having a receiving hole configured to receive the probe formed therein, the upper plate being configured to support an upper side of the probe, a lower plate having a receiving hole configured to receive the probe formed therein, the lower plate being configured to support a lower side of the probe, and a spacer disposed between the upper plate and the lower plate, the spacer being configured to separate the upper plate and the lower plate from each other by a predetermined distance in order to stably support the probe and to provide a space in which the probe is deformed.

During testing, a contact tip of the probe of the probe head is worn due to contact pressure thereof or due to scrubbing between the contact tip of the probe and a contact terminal of the object to be tested.

As a result, the overall lifespan of the probe head is shortened, whereby the number of tests is limited. In addition, work time for replacement and reinstallation of the probe head is added, whereby a test process is delayed and production cost is increased.

### DISCLOSURE

### Technical Problem

It is an object of the present invention to provide a probe head configured such that a support distance is changed based on variation of a support axis extending through a plate and a spacer, whereby the protrusion length of a probe is adjusted.

### Technical Solution

In accordance with the present invention, the above and other objects can be accomplished by the provision of a probe head for testing semiconductor elements, the probe head including an upper plate having a first receiving hole formed therein, a lower plate formed spaced apart from the upper plate, the lower plate having a second receiving hole formed therein, a probe coupled to the upper plate and the lower plate such that an upper part of the probe is received in the first receiving hole, whereby an upper tip protrudes upwards from the upper plate, and a lower part of the probe is received in the second receiving hole, whereby a lower tip protrudes downwards from the lower plate, and a spacer formed between the upper plate and the lower plate to separate the upper plate and the lower plate from each other while supporting the upper plate and the lower plate, thereby providing a space portion capable of receiving a middle part of the probe, wherein a support distance is changed based on variation of a support axis extending through the upper plate, the lower plate, and the spacer in order to adjust the height of the space portion, whereby the protrusion length of the lower tip of the probe under the lower plate is adjustable.

The spacer may be constituted by a plurality of blocks arranged in a horizontal direction, the blocks may be formed so as to have sequentially increased or decreased heights, and the blocks may be selectively movable.

In addition, the spacer may be constituted by a plurality of plate-shaped blocks or a plurality of pillar-shaped blocks arranged in parallel to a direction toward corners of the upper plate and the lower plate.

The plate-shaped blocks may be assembled such that the direction in which the support axis is varied is a direction toward the center of the space portion and the support distance is decreased toward the center of the space portion, and the plate-shaped blocks may be formed at corners of the upper plate and the lower plate that face each other or may be formed at four corners of the upper plate and the lower plate so as to have a quadrangular frame shape.

The pillar-shaped blocks may be assembled such that the support axis is varied along corners of the space portion and the support distance is decreased toward the center of the space portion along the corners thereof.

The plurality of blocks may have different colors, and an indicator for discrimination may be provided at a surface of each of the plurality of blocks.

A screw engagement structure and an adhesion structure may be singly or mixedly formed at coupling surfaces of the spacer and each of the upper plate and the lower plate that face each other.

Meanwhile, an inner surface of each of the upper plate and the lower plate may be formed so as to have multiple steps such that the support distance is decreased from the center to the outside thereof or from the outside to the center thereof.

The multiple steps formed at the inner surface of each of the upper plate and the lower plate may have different colors, and an indicator for discrimination may be provided at a surface of each of the multiple steps formed at the inner surface of each of the upper plate and the lower plate.

When the support distance is decreased from the center to the outside thereof, the multiple steps formed at each of the upper plate and the lower plate may have heights increased from the center to the outside thereof. In addition, when the support distance is decreased from the outside to the center thereof, the multiple steps formed at each of the upper plate and the lower plate may have heights decreased from the outside to the center thereof.

A concave-convex structure, a screw engagement structure, and an adhesion structure may be singly or mixedly formed at coupling surfaces of the spacer, the upper plate, and the lower plate, arranged along the support axis, which face each other.

### Advantageous Effects

As is apparent from the above description, the present invention, which relates to a probe head configured such that a support distance is changed based on variation of a support axis extending through a plate and a spacer, whereby the protrusion length of a probe is adjusted, has the following effects.

First, the present invention has an effect in that the protrusion length of the probe under a lower plate is adjusted, whereby the number of tests is increased, and therefore the lifespan of the probe head is extended.

Second, the present invention has another effect in that work time for replacement and reinstallation of the probe head is shortened, whereby delay of a test process is prevented and process cost is reduced.

Third, the present invention has a further effect in that the protrusion length of the probe is adjustable depending on the degree of wear of the probe, whereby contact between a printed circuit board and a contact terminal of an object to be tested at an appropriate pressure is achieved, and therefore more precise and accurate tests are possible while the printed circuit board and the contact terminal of the object to be tested are protected.

### BRIEF DESCRIPTION OF THE DRAWINGS

The above and other objects, features and other advantages of the present invention will be more clearly understood from the following detailed description taken in conjunction with the accompanying drawings, in which:

FIGS. 1 to 7 are schematic views showing various embodiments of a probe head with an adjustable protrusion length of a probe according to the present invention.

### DETAILED DESCRIPTION OF THE PREFERRED EMBODIMENTS

The present invention relates to a probe head for testing semiconductor elements, and more particularly to a probe head configured such that a support distance is changed based on variation of a support axis extending through a plate and a spacer, whereby the protrusion length of a probe is adjusted.

The protrusion length of the probe under a lower plate is adjusted, whereby the number of tests is increased, and therefore the lifespan of the probe head is extended. In addition, work time for replacement and reinstallation of the probe head is shortened, whereby delay of a test process is prevented and process cost is reduced.

Furthermore, the protrusion length of the probe is adjustable depending on the degree of wear of the probe, whereby contact between a printed circuit board and a contact terminal of an object to be tested at an appropriate pressure is achieved, and therefore more precise and accurate tests are possible while the printed circuit board and the contact terminal of the object to be tested are protected.

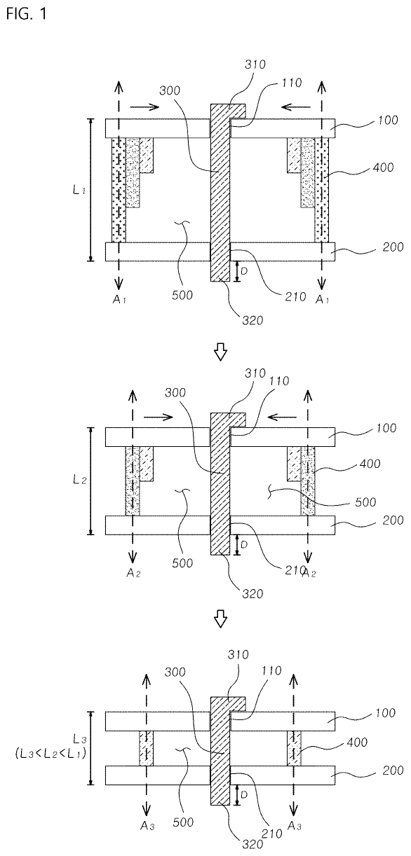

Hereinafter, embodiments of the present invention will be described in detail with reference to the accompanying drawings. FIGS. 1 to 7 are schematic views showing various embodiments of a probe head with an adjustable protrusion length of a probe according to the present invention.

As shown, the probe head with the adjustable protrusion length of the probe 300 according to the present invention includes an upper plate 100 having a first receiving hole 110 formed therein, a lower plate 200 formed spaced apart from the upper plate 100, the lower plate 200 having a second receiving hole 210 formed therein, a probe 300 coupled to the upper plate 100 and the lower plate 200 such that an upper part of the probe is received in the first receiving hole 110, whereby an upper tip 310 protrudes upwards from the upper plate 100, and a lower part of the probe is received in the second receiving hole 210, whereby a lower tip 320 protrudes downwards from the lower plate 200, and a spacer 400 formed between the upper plate 100 and the lower plate 200 to separate the upper plate 100 and the lower plate 200 from each other while supporting the upper plate 100 and the lower plate 200, thereby providing a space portion 500 capable of receiving a middle part of the probe 300, wherein a support distance is changed based on variation of a support axis extending through the upper plate 100, the lower plate 200, and the spacer 400 in order to adjust the height of the space portion 500, whereby the protrusion length of the lower tip 320 of the probe 300 under the lower plate 200 is adjustable.

The probe head according to the present invention mainly includes an upper plate 100, a lower plate 200, a probe 300 coupled to the upper plate 100 and the lower plate 200, and a spacer configured to separate the upper plate 100 and the lower plate 200 from each other and to support the upper plate 100 and the lower plate 200.

In particular, the spacer 400 according to the present invention is configured to be movable between the upper plate 100 and the lower plate 200, and a support axis extending through the upper plate 100, the lower plate 200, and the spacer 400 is varied to change a support distance, whereby the height of a space portion 500 defined by the upper plate 100, the lower plate 200, and the spacer 400 is adjusted, and therefore the protrusion length of the probe 300 is adjustable.

In general, while a semiconductor element is tested, a contact tip of the probe 300 is worn due to contact pressure against a printed circuit board and an object to be tested or due to scrubbing between the contact tip of the probe 300 and a contact terminal of the object to be tested.

As a result, the overall lifespan of the probe head is shortened, whereby the number of tests is limited. In addition, work time for replacement and reinstallation of the probe head is added, whereby a test process is delayed and production cost is increased.

That is, since the protrusion length of the probe 300 is decreased as the number of tests is increased, the position of the spacer 400 is moved between the upper plate 100 and the lower plate 200 to change a support distance by the spacer 400, whereby the protrusion length of the lower tip 320 of the probe 300 under the lower plate 200 is adjustable. As a result, the probe 300 is brought into contact with the printed circuit board and the contact terminal of the object to be tested at an appropriate pressure, whereby the number of tests is increased in the state in which more precise and accurate tests are possible.

The probe 300 according to the present invention may have any shape or may be made of any material in order to test conventional semiconductor elements. In addition, each of the upper plate 100 and the lower plate 200 may have any shape as long as it is possible to stably receive the probe 300 and to guide and support a space portion in which the probe 300 is slid, received, and moved. Furthermore, each of the upper plate 100 and the lower plate 200 may be provided in single or plural in order to stably and effectively support the probe 300 depending on the probe 300.

Several thousands to several tens of thousands of probes 300 are coupled to the receiving holes of the upper plate 100 and the lower plate 200, and are repeatedly slid upwards and downwards and bent in the receiving holes to perform tests. In the present invention, a description will be given based on the structure in which one probe 300 is coupled to the upper plate 100 and the lower plate 200 for sake of convenience.

A probe head according to an embodiment of the present invention includes an upper plate 100 having a first receiving hole 110 formed therein, a lower plate 200 formed spaced apart from the upper plate 100, the lower plate 200 having a second receiving hole 210 formed therein, and a probe 300 coupled to the upper plate 100 and the lower plate 200 such that an upper part of the probe is received in the first receiving hole 110, whereby an upper tip 310 protrudes upwards from the upper plate 100, and a lower part of the probe is received in the second receiving hole 210, whereby a lower tip 320 protrudes downwards from the lower plate 200.

Here, the probe 300 may be made of an elastic metal or a metal composite material that has elasticity, and a needle type pin, which is usually called a cobra pin, may be provided as the probe 300. The upper tip 310 protrudes upwards from the upper plate 100, and the lower part of the probe is received in the second receiving hole 210, whereby the probe 300 is brought into stable contact with the printed circuit board and the contact terminal of the object to be tested while being bent in the space portion 500.

The spacer 400 according to the present invention is formed between the upper plate 100 and the lower plate 200 to separate the upper plate 100 and the lower plate 200 from each other, thereby providing a space portion 500 capable of receiving a middle part of the probe 300.

The spacer 400 is formed between the upper plate 100 and the lower plate 200 so as to separate the upper plate 100 and the lower plate 200 from each other and to support the upper plate 100 and the lower plate 200, and provides a space portion 500 in which the probe 300 may be moved or bent.

The spacer 400 is formed so as to have a quadrangular frame shape such that the space portion 500 is formed in a closed state or is formed so as to have a plurality of bridges located at symmetrical points such that the space portion 500 is formed in an open state.

That is, the spacer 400 is formed along the circumference of each of the upper plate 100 and the lower plate 200 at corners or adjacent to the corners thereof in response to the shape of each of the upper plate 100 and the lower plate 200 so as to have a quadrangular frame shape, whereby the space portion 500 is formed so as to be surrounded by the upper plate 100, the lower plate 200, and the quadrangular-frame-shaped spacer.

Alternatively, the spacer 400 is formed so as to have bridges located at symmetrical points, e.g. opposite corners or vertices of the upper plate 100 and the lower plate 200, or adjacent thereto such that the space portion 500 is formed in an open state.

The probe head according to the present invention is configured such that the support distance is changed based on variation of the support axis extending through the upper plate 100, the lower plate 200, and the spacer 400 in order to adjust the height of a space portion 500, whereby the protrusion length of the lower tip 320 of the probe 300 under the lower plate 200 is adjustable.

FIGS. 1 to 7 show various embodiments of the present invention, wherein the upper plate 100, the lower plate 200, the spacer 400 formed between the upper plate 100 and the lower plate 200, and the probe 300 coupled to the upper plate 100 and the lower plate 200 are schematically shown.

The present invention is mainly configured to have two different embodiments.

In one embodiment, the spacer 400 is constituted by a plurality of blocks having different lengths, the blocks are arranged in a horizontal direction, any one of the blocks is removed to change the spacer 400 that supports the plates (variation of the support axis, A1, A2, A3, B1, or B2), whereby the support distance between the upper plate 100 and the lower plate 200 by the space 400 is changed, and therefore the height (L1, L2, L3, S1, or S2) of the space portion 500 is adjusted. As a result, the protrusion length of the lower tip 320 of the probe 300 under the lower plate 200 is adjustable.

Specifically, the spacer 400 according to the present invention is constituted by a plurality of blocks arranged in the horizontal direction, the blocks are formed so as to have sequentially increased or decreased heights, and the blocks are selectively movable, whereby the support distance based on variation of the support axis extending through the plates by the spacer 400 is changed.

In other embodiment, one spacer 400 having a specific length is formed, each of the upper plate 100 and the lower plate 200 is formed so as to have multiple steps, and the spacer 400 is moved to each of the steps (variation of the support axis), whereby the support distance between the upper plate 100 and the lower plate 200 by the spacer 400 is changed, and therefore the height of the space portion 500 is adjusted.

Specifically, the spacer 400 according to the present invention is formed as a single member, an inner surface of each of the upper plate 100 and the lower plate 200 is formed so as to have multiple steps such that the support distance is decreased from the center to the outside thereof or from the outside to the center thereof, and the spacer 400 is moved to a specific one of the steps of each of the upper plate 100 and the lower plate 200, whereby the support distance based on variation of the support axis extending through the plates by the spacer 400 is changed.

That is, when the probe 300 is worn and thus the length of the probe 300 is decreased during testing, one or more of the blocks having different lengths constituting the spacer 400 is removed or the spacer 400 is moved between the plates having multiple steps by a length corresponding thereto or by a length necessary to maintain appropriate contact pressure against the printed circuit board and the contact terminal of the object to be tested as needed, whereby the height of the space portion 500 is adjusted, and therefore the protrusion length of the lower tip 320 of the probe 300 under the lower plate 200 is adjusted.

Meanwhile, in the embodiment in which the plurality of blocks is arranged in the horizontal direction, the blocks are formed so as to have sequentially increased or decreased heights. In addition, the blocks may be formed so as to have different colors. Alternatively, an indicator for discrimination may be further provided at the surface of each block.

As a result, a block to be removed is easily recognized, whereby the height of the space portion 500 is conveniently adjusted. That is, a block having a specific width, height, or color is easily distinguished from the other blocks, and whereby removal of a wrong block is minimized and removal of a correct block is rapidly and easily achieved when adjusting the height of the space portion 500.

In addition, an indicator for discrimination in height or position, e.g. an Arabic numeral, a Korean consonant, or a letter, may be marked on the surface of each block such that the indicator can be recognized from outside, whereby a block having a specific height is accurately and rapidly removed.

A screw engagement structure 600 and an adhesion structure are singly or mixedly formed at coupling surfaces of the spacer 400 and each of the upper plate 100 and the lower plate 200 that face each other such that the coupling surfaces are coupled to each other.

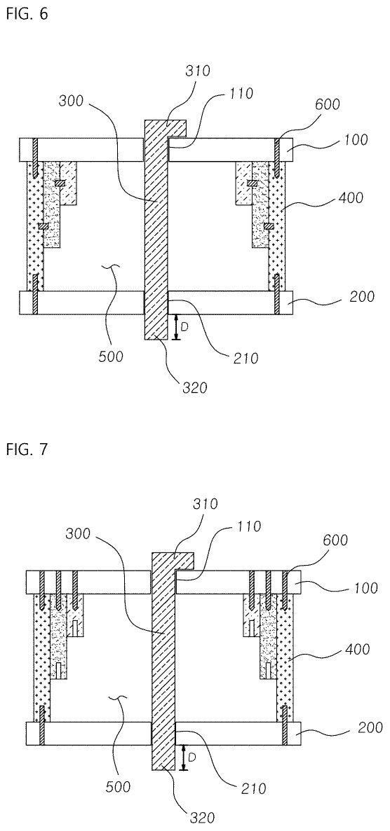

That is, as shown in FIGS. 6 and 7, the spacer 400 constituted by the plurality of blocks is stably coupled to each of the upper plate 100 and the lower plate 200 via a coupling means, such as the screw engagement structure 600 or the adhesion structure, and is easily separated from each of the upper plate 100 and the lower plate 200 when the spacer 400 is removed. In addition, coupling surfaces of adjacent blocks of the spacer 400 that face each other are stably coupled to each other via the coupling means, such as the screw engagement structure 600 or the adhesion structure (see FIG. 6).

Alternatively, a screw hole for screw engagement (see FIG. 7) or an adhesive member may be formed in advance at a coupling surface of each block of the spacer 400 that is to be coupled to the coupling surface of a corresponding one of the other blocks.

In the screw engagement structure 600, a screw hole for screw engagement is formed in each of the coupling surfaces that face each other such that the coupling surfaces are coupled to each other by screw engagement. In the adhesion structure, an adhesive member is formed on each of the coupling surfaces that face each other such that the coupling surfaces are coupled to each other by adhesion.

Also, in the embodiment in which each of the upper plate 100 and the lower plate 200 is formed so as to have multiple steps, the steps are formed so as to have different colors, or an indicator for discrimination is further provided at the surface of each step.

As a result, each block to which the spacer 400 is moved and coupled is easily recognized, whereby the height of the space portion 500 is conveniently adjusted. That is, each step having a specific color or a specific indicator is easily distinguished from the other steps, whereby coupling between the spacer 400 and a wrong step is minimized and movement of the spacer 400 is rapidly and easily achieved when adjusting the height of the space portion 500.

An Arabic numeral, a Korean consonant, or a letter is marked as the indicator such that the indicator can be recognized from outside, whereby coupling between the spacer 400 and a specific step is rapidly achieved.

A concave-convex structure, a screw engagement structure 600, and an adhesion structure are singly or mixedly formed at coupling surfaces of the spacer 400, the upper plate 100, and the lower plate 200, arranged along the support axis, which face each other such that the coupling surfaces are coupled to each other.

That is, the spacer 400 is separated from the upper plate 100 and the lower plate 200, the spacer 400 is located at a desired one of the steps of each of the upper plate 100 and the lower plate 200, and each step and the spacer 400 are stably coupled to each other via the coupling means, such as the screw engagement structure 600 or the adhesion structure. In addition, the spacer 400 is easily separated from the step of each plate when the spacer 400 is removed.

In addition, a screw hole for screw engagement or an adhesive member may be formed in advance at a coupling surface of each step to be coupled.

In the screw engagement structure 600, a screw hole for screw engagement is formed in each of the coupling surfaces that face each other such that the coupling surfaces are coupled to each other by screw engagement. In the adhesion structure, an adhesive member is formed on each of the coupling surfaces that face each other such that the coupling surfaces are coupled to each other by adhesion.

Not only coupling between the plate and the spacer 400 but also coupling between the blocks constituting the spacer 400 is stably performed by the coupling means. In addition, the blocks constituting the spacer 400 are separated from each other by screw disengagement and separation between the adhesive members, and then movement and recoupling of the spacer 400 are easily performed.

Hereinafter, various embodiments of the present invention will be described with reference to the accompanying drawings. In the drawings showing the embodiments of the present invention, the height of each block constituting the spacer 400, the height of each step of the plate, the protrusion length of the lower tip 320 of the probe 300, etc. are somewhat exaggerated for convenience of description. Actually, the height of each block constituting the spacer 400 or the height of each step of the plate is set in consideration of the degree of wear of the probe 300, and a change in height of the space portion 500 due to movement of the spacer 400 is set so as to be similar to the degree of wear of the probe 300.

### First Embodiment

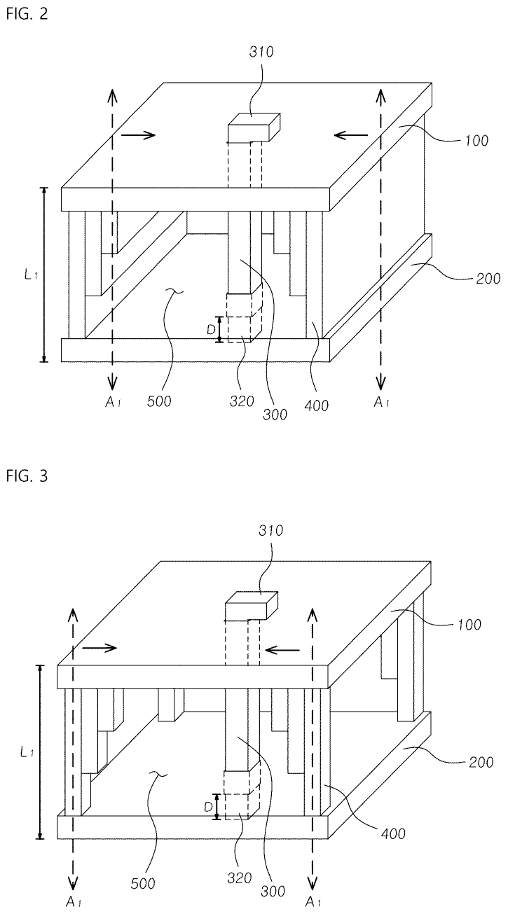

FIGS. 1 and 2 show a first embodiment of the present invention, wherein an upper plate 100, a lower plate 200, a spacer 400 formed between the upper plate 100 and the lower plate 200, and a probe 300 coupled to the upper plate 100 and the lower plate 200 are schematically shown.

The spacer 400 is constituted by three plate-shaped blocks arranged in the horizontal direction, the blocks are formed such that the heights of the blocks are decreased in a direction toward the center of a space portion 500, and when the probe 300 is shortened, the outermost block is removed to adjust the height of the space portion 500.

When the three blocks are located as shown in FIG. 1, the support axis extending through the block coupled to the upper plate 100 and the lower plate 200 (the outermost block of the spacer 400) is A1. At this time, the support distance by the block based on the support axis A1 is L1.

When the probe 300 is shortened, an outermost one of the three blocks is removed. As a result, the support axis extending through the block coupled to the upper plate 100 and the lower plate 200 is A2. At this time, the support distance by the block based on the support axis A2 is L2.

When the probe 300 is further shortened, a middle one of the three blocks is removed. As a result, the support axis extending through the block coupled to the upper plate 100 and the lower plate 200 is A3. At this time, the support distance by the block based on the support axis A3 is L3.

In the first embodiment of the present invention, the direction in which the support axis is varied is a direction toward the center of the space portion 500, and the support distance is decreased toward the center of the space portion 500, whereby the protrusion length of the probe 300 is adjusted.

In the first embodiment of the present invention, as shown in FIGS. 1 and 2, the spacer 400 is constituted by a plurality of plate-shaped blocks arranged in parallel to a direction toward corners of the upper plate 100 and the lower plate 200, wherein the plate-shaped blocks are formed at corners of the upper plate 100 and the lower plate 200 that face each other such that the space portion 500 is formed in an open state or may be formed at four corners of the upper plate 100 and the lower plate 200 so as to have a quadrangular frame shape such that the space portion 500 is formed in a closed state.

In this case, the plate-shaped blocks are assembled such that the direction in which the support axis is varied is a direction toward the center of the space portion 500 and the support distance is decreased toward the center of the space portion 500.

When the probe 300 is worn during testing, whereby the protrusion length of the lower tip 320 of the probe 300 under the lower plate is decreased, scrubbing between the lower tip and a contact terminal of an object to be tested is not sufficiently performed or appropriate contact pressure against a printed circuit board and the contact terminal of the object to be tested is not maintained. In this case, the blocks constituting the spacer 400 are sequentially removed from the longest block (the direction in which the support axis is varied is a direction toward the center of the space portion 500, as indicated by an arrow) to reduce the height of the space portion 500 (L1->L2->L3, L1>L2>L3), whereby the protrusion length of the lower tip 320 of the probe 300 is readjusted to D.

### Second Embodiment

FIGS. 1 and 3 show a second embodiment of the present invention, wherein an upper plate 100, a lower plate 200, a spacer 400 formed between the upper plate 100 and the lower plate 200, and a probe 300 coupled to the upper plate 100 and the lower plate 200 are schematically shown.

In the second embodiment, the spacer 400 is constituted by three pillar-shaped blocks, the blocks are formed so as to be arranged adjacent to vertices of the upper plate 100 and the lower plate 200 along corners thereof in the horizontal direction, and heights of the blocks are decreased in a direction toward a space portion 500, unlike the first embodiment. When the probe 300 is shortened, therefore, the outermost block is removed to adjust the height of the space portion 500.

When the three blocks are located adjacent to each of the four vertices, as shown in FIGS. 1 and 3, the support axis extending through the block coupled to the upper plate 100 and the lower plate 200 (the outermost block of the spacer 400) is A1. At this time, the support distance by the block based on the support axis A1 is L1.

When the probe 300 is shortened, an outermost one of the three blocks located adjacent to each of the four vertices is removed. As a result, the support axis extending through the block coupled to the upper plate 100 and the lower plate 200 is A2. At this time, the support distance by the block based on the support axis A2 is L2.

When the probe 300 is further shortened, a middle one of the three blocks located adjacent to each of the four vertices is removed. As a result, the support axis extending through the block coupled to the upper plate 100 and the lower plate 200 is A3. At this time, the support distance by the block based on the support axis A3 is L3.

In the second embodiment of the present invention, the variation direction of the support axis is varied along the corners, and the support distance is decreased toward the center of the space portion 500 along the corners thereof, whereby the protrusion length of the probe 300 is adjusted.

In the first embodiment of the present invention, as shown in FIG. 3, the spacer 400 is constituted by a plurality of pillar-shaped blocks arranged in parallel along the corners of the upper plate 100 and the lower plate 200 so as to be adjacent to the four vertices thereof, wherein the pillar-shaped blocks are formed along the corners of the upper plate 100 and the lower plate 200 that face each other such that the space portion 500 is formed in an open state.

In this case, the pillar-shaped blocks are assembled such that the variation direction of the support axis is varied along the corners of the space portion 500 and the support distance is decreased toward the center of the space portion 500 along the corners thereof.

When the probe 300 is worn during testing, whereby the protrusion length of the lower tip 320 of the probe 300 under the lower plate is decreased, scrubbing between the lower tip and a contact terminal of an object to be tested is not sufficiently performed or appropriate contact pressure against a printed circuit board and the contact terminal of the object to be tested is not maintained. In this case, the blocks constituting the spacer 400 are sequentially removed from the longest block (the variation direction of the support axis is varied along the corners of the plate, as indicated by an arrow) to reduce the height of the space portion 500 (L1->L2->L3, L1>L2>L3), whereby the protrusion length of the lower tip 320 of the probe 300 is readjusted to D.

### Third Embodiment

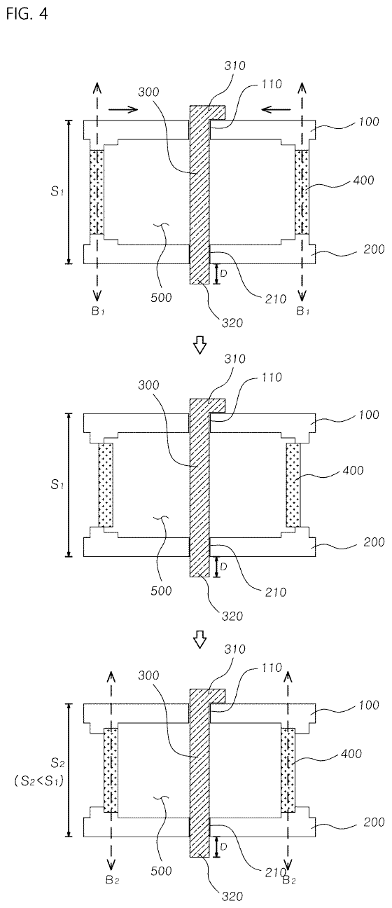

FIG. 4 shows a third embodiment of the present invention, wherein an upper plate 100, a lower plate 200, a spacer 400 formed between the upper plate 100 and the lower plate 200, and a probe 300 coupled to the upper plate 100 and the lower plate 200 are schematically shown.

In the third embodiment of the present invention, an inner surface of each of the upper plate 100 and the lower plate 200 is formed so as to have multiple steps such that the support distance is decreased from the center to the outside thereof. A single spacer 400 is coupled to each of the steps of each of the upper plate 100 and the lower plate 200. As the spacer 400 is coupled to the respective steps having different heights, the height of the space portion 500 is changed. When the probe 300 is shortened, therefore, the spacer 400 located at the outermost step of the plate is sequentially moved to the next inner step to the outermost step, whereby the support distance based on variation of the support axis is changed, and therefore the height of the space portion 500 is adjusted.

When the spacer 400 is located at the outermost step of the plate, as shown in FIG. 4, the support axis extending through the spacer 400 coupled to the upper plate 100 and the lower plate 200 is B1. At this time, the support distance by the spacer 400 based on the support axis B1 is S1.

When the probe 300 is shortened, the spacer 400 is moved to the next inner step to the outermost step of the plate. As a result, the support axis extending through the spacer 400 coupled to the upper plate 100 and the lower plate 200 is B2. At this time, the support distance by the spacer 400 based on the support axis B2 is S2.

When the probe 300 is further shortened (not shown), the spacer 400 is moved to the second next inner step of the plate. As a result, the support axis extending through the spacer 400 coupled to the upper plate 100 and the lower plate 200 is further moved toward the center of the plate. At this time, the support distance by the spacer 400 based on the support axis is further decreased.

When the probe 300 is worn during testing, whereby the protrusion length of the lower tip 320 of the probe 300 under the lower plate is decreased, scrubbing between the lower tip and a contact terminal of an object to be tested is not sufficiently performed or appropriate contact pressure against a printed circuit board and the contact terminal of the object to be tested is not maintained. In this case, the spacer 400 is sequentially moved to any one of the steps in the direction toward the center of the plate (the direction in which the support axis is varied in the direction toward the center of the plate, as indicated by an arrow) to reduce the height of the space portion 500 (S1->S2, S1 >S2), whereby the protrusion length of the lower tip 320 of the probe 300 is readjusted to D.

### Fourth Embodiment

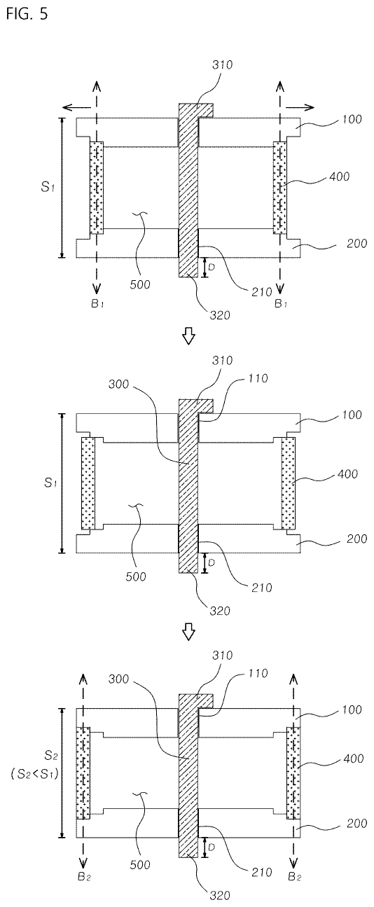

FIG. 5 shows a fourth embodiment of the present invention, wherein an upper plate 100, a lower plate 200, a spacer 400 formed between the upper plate 100 and the lower plate 200, and a probe 300 coupled to the upper plate 100 and the lower plate 200 are schematically shown.

In the fourth embodiment of the present invention, an inner surface of each of the upper plate 100 and the lower plate 200 is formed so as to have multiple steps such that the support distance is decreased from the outside to the center thereof. A single spacer 400 is coupled to each of the steps of each of the upper plate 100 and the lower plate 200. As the spacer 400 is coupled to the respective steps having different heights, the height of the space portion 500 is changed. When the probe 300 is shortened, therefore, the spacer 400 located at the innermost step of the plate is sequentially moved to the next outer step to the innermost step, whereby the support distance based on variation of the support axis is changed, and therefore the height of the space portion 500 is adjusted.

When the spacer 400 is located at the innermost step of the plate, as shown in FIG. 5, the support axis extending through the spacer 400 coupled to the upper plate 100 and the lower plate 200 is B1. At this time, the support distance by the spacer 400 based on the support axis B1 is S1.

When the probe 300 is shortened, the spacer 400 is moved to the next outer step to the innermost step of the plate. As a result, the support axis extending through the spacer 400 coupled to the upper plate 100 and the lower plate 200 is B2. At this time, the support distance by the spacer 400 based on the support axis B2 is S2.

When the probe 300 is further shortened (not shown), the spacer 400 is moved to the second next outer step of the plate. As a result, the support axis extending through the spacer 400 coupled to the upper plate 100 and the lower plate 200 is further moved toward the outside of the plate. At this time, the support distance by the spacer 400 based on the support axis is further decreased.

When the probe 300 is worn during testing, whereby the protrusion length of the lower tip 320 of the probe 300 under the lower plate is decreased, scrubbing between the lower tip and a contact terminal of an object to be tested is not sufficiently performed or appropriate contact pressure against a printed circuit board and the contact terminal of the object to be tested is not maintained. In this case, the spacer 400 is sequentially moved to any one of the steps in the direction toward the outside of the plate (the direction in which the support axis is varied in the direction toward the outside of the plate, as indicated by an arrow) to reduce the height of the space portion 500 (S1->S2, S1 >S2), whereby the protrusion length of the lower tip 320 of the probe 300 is readjusted to D.

As described above, the present invention relates to a probe head for testing semiconductor elements, and more particularly to a probe head configured such that a support distance is changed based on variation of a support axis extending through a plate and a spacer, whereby the protrusion length of a probe is adjusted.

The protrusion length of the probe under a lower plate is adjusted, whereby the number of tests is increased, and therefore the lifespan of the probe head is extended. In addition, work time for replacement and reinstallation of the probe head is shortened, whereby delay of a test process is prevented and process cost is reduced.

Furthermore, the protrusion length of the probe is adjustable depending on the degree of wear of the probe, whereby contact between a printed circuit board and a contact terminal of an object to be tested at an appropriate pressure is achieved, and therefore more precise and accurate tests are possible while the printed circuit board and the contact terminal of the object to be tested are protected.

What is claimed is:

1. A probe head for testing semiconductor elements, the probe head comprising:
an upper plate having a first receiving hole formed therein;
a lower plate formed spaced apart from the upper plate, the lower plate having a second receiving hole formed therein;
a probe coupled to the upper plate and the lower plate such that an upper part of the probe is received in the first receiving hole, whereby an upper tip protrudes upwards from the upper plate, and a lower part of the probe is received in the second receiving hole, whereby a lower tip protrudes downwards from the lower plate; and
a spacer formed between the upper plate and the lower plate to separate the upper plate and the lower plate from each other while supporting the upper plate and the lower plate, thereby providing a space portion capable of receiving a middle part of the probe, wherein
a support distance is changed based on variation of a support axis extending through the upper plate, the lower plate, and the spacer in order to adjust the height of the space portion, whereby a protrusion length of the lower tip of the probe under the lower plate is adjustable.

2. The probe head according to claim 1, wherein
the spacer is constituted by a plurality of blocks arranged in a horizontal direction,
the blocks are formed so as to have sequentially increased or decreased heights, and
the blocks are selectively movable.

3. The probe head according to claim 2, wherein the spacer is constituted by a plurality of plate-shaped blocks or a plurality of pillar-shaped blocks arranged in parallel to a direction toward corners of the upper plate and the lower plate.

4. The probe head according to claim 3, wherein the plate-shaped blocks are assembled such that a direction in which the support axis is varied is a direction toward a center of the space portion and the support distance is decreased toward the center of the space portion.

5. The probe head according to claim 4, wherein the plate-shaped blocks are formed at corners of the upper plate and the lower plate that face each other or are formed at four corners of the upper plate and the lower plate so as to have a quadrangular frame shape.

6. The probe head according to claim 3, wherein the pillar-shaped blocks are assembled such that the support axis is varied along corners of the space portion and the support distance is decreased toward a center of the space portion along the corners thereof.

7. The probe head according to claim 2, wherein the plurality of blocks has different colors.

8. The probe head according to claim 2, wherein an indicator for discrimination is provided at a surface of each of the plurality of blocks.

9. The probe head according to claim 2, wherein a screw engagement structure and an adhesion structure are singly or mixedly formed at coupling surfaces of the spacer and each of the upper plate and the lower plate that face each other.

10. The probe head according to claim 1, wherein an inner surface of each of the upper plate and the lower plate is formed so as to have multiple steps such that the support distance is decreased from a center to an outside thereof or from the outside to the center thereof.

11. The probe head according to claim 10, wherein the multiple steps formed at the inner surface of each of the upper plate and the lower plate have different colors.

12. The probe head according to claim 10, wherein an indicator for discrimination is provided at a surface of each of the multiple steps formed at the inner surface of each of the upper plate and the lower plate.

13. The probe head according to claim 10, wherein
when the support distance is decreased from the center to the outside thereof,
the multiple steps formed at each of the upper plate and the lower plate have heights increased from the center to the outside thereof.

14. The probe head according to claim 10, wherein
when the support distance is decreased from the outside to the center thereof,
the multiple steps formed at each of the upper plate and the lower plate have heights decreased from the outside to the center thereof.

15. The probe head according to claim 10, wherein a concave-convex structure, a screw engagement structure, and an adhesion structure are singly or mixedly formed at coupling surfaces of the spacer, the upper plate, and the lower plate, arranged along the support axis, which face each other.
